(19) United States
(12) Patent Application Publication
(10) Pub. No.: US 2025/0043422 A1
(43) Pub. Date: Feb. 6, 2025

(54) METHOD, SYSTEM AND APPARATUS FOR TREATING SUBSTRATE SURFACE

(71) Applicant: ASM IP Holding B.V., Almere (NL)

(72) Inventors: Fu Tang, Gilbert, AZ (US); Eric Shero, Phoenix, AZ (US); Michael Eugene Givens, Oud-Heverlee (BE)

(21) Appl. No.: 18/786,895

(22) Filed: Jul. 29, 2024

Related U.S. Application Data
(60) Provisional application No. 63/529,993, filed on Jul. 31, 2023.

(51) Int. Cl. C23C 16/455; C23C 16/02; C23C 16/40

(52) U.S. Cl. CPC C23C 16/45551; C23C 16/0236; C23C 16/402; C23C 16/407

(57) ABSTRACT

A method for depositing one or more layers on a substrate is disclosed. The method may comprise providing a substrate, etching a native oxide from a surface of the substrate responsive to exposure to an etchant, contacting an etched surface of the substrate with an oxidizing agent oxidizing a first layer of the substrate responsive to contact with the oxidizing agent and depositing a second layer on the first layer.

### CROSS-REFERENCE TO RELATED APPLICATIONS

This application is a nonprovisional of, and claims priority to and the benefit of, U.S. Provisional Patent Application No. 63/529,993, filed Jul. 31, 2023 and entitled “METHOD, SYSTEM AND APPARATUS FOR TREATING SUBSTRATE SURFACE,” which is hereby incorporated by reference herein.

### FIELD OF THE DISCLOSURE

The present disclosure generally relates to the field of semiconductor processing methods and systems, and to the field of electronic devices, and in particular, to substrate surface treatments to reduce defects.

### BACKGROUND OF THE DISCLOSURE

The scaling of semiconductor devices, such as, complementary metal-oxide-semiconductor (CMOS) devices, has led to significant improvements in speed and density of integrated circuits. However, the drive to manufacture increasingly complex structures for future technology nodes while at the same time striving to maintain or improve throughput is a significant challenge. Nucleation delay of thin film deposition contributes to this challenge by not only reducing throughput but also introducing defects in device layers that may lead to device failures. Thus, there is a continued need to mitigate nucleation delay.

One cause of nucleation delay can be removal of native oxide from a surface of Si and SiGe substrate. Native oxide material may form on a substrate surface due to exposure of the substrate to oxygen during the integrated circuit fabrication process, e.g., exposure to ambient air during transfer of the substrate between fabrication systems, or residual oxidizing agents within fabrication systems. Native oxides typically lack uniformity and are rife with defects. Thus, the native oxide layer will be removed (e.g., by etching with hydrogen fluoride (HF)) prior to film deposition. However, after removal of the native oxide, the surface of the substrate may be hydrogen terminated. Such, hydrogen termination (e.g., Si—H) may be inert causing nucleation delay of subsequent deposition films and may further produce island type film growth instead of smooth 2D type film growth. Where islands merge, as film grows thicker, the boundary formed by merging grains could have weak physical properties, for example, merged boundaries may be easier to etch, or may be more likely to become a current leakage path.

Conventional approaches to resolve this nucleation delay and island growth use wet bench methods (e.g., ozonate water or RCA-1 cleaning) which increase throughput delay because wet bench modules are not integrated with reaction chambers where subsequent film deposition will take place.

Such systems and methods for mitigating nucleation delay have generally been considered suitable for their intended purpose. However, there remains a need in the art for improved methods of reducing nucleation delay. The present disclosure provides a solution to this need.

### SUMMARY OF THE DISCLOSURE

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

In one aspect, a method for depositing one or more layers on a substrate is disclosed. The method may comprise providing a substrate, etching a native oxide from a surface of the substrate responsive to exposure to an etchant, contacting an etched surface of the substrate with an oxidizing agent oxidizing a first layer of the substrate responsive to contact with the oxidizing agent and depositing a second layer on the first layer.

In some examples, the etchant may be a chemical in gas phase. Alternatively, the etchant may be a chemical in liquid phase. The etchant may comprise hydrogen chloride (HCl), hydrogen fluoride (HF), ammonium hydroxide (NH4OH), or hydrogen (H2) or a combination thereof. The substrate may comprise silicon (Si), germanium (Ge) or silicon germanium (SiGe).

In some examples, the oxidizing agent may comprise a weaker oxidizer than ozone (O3). The oxidizing agent may comprise H2O2 and/or may contact the substrate in a vapor phase. Oxidizing the first layer of the substrate may further comprise oxidizing the substrate to a depth of less than 10 angstroms with respect to a top surface of the substrate.

In some examples, oxidizing the first layer of the substrate may further comprise oxidizing the substrate to a depth of less than five angstroms with respect to a top surface of the substrate. Oxidizing the first layer of the substrate may further comprise hydroxylating a portion of the molecules at the etched surface of the substrate.

In some examples, the contacting the surface of the substrate with the oxidizing agent may further comprise modifying the temperature of the substrate while in contact with the oxidizer based on a desired thickness of the first oxide layer. Controlling the temperature of the substrate may further comprise heating the susceptor (e.g., susceptor 6 or 106) coupled to the substrate 30 or adjusting a temperature of the oxidizing agent contacting the substrate 30.

In some examples, the first layer may comprise a first oxide layer and wherein the second layer is a second oxide layer. The first oxide layer may comprise silicon oxide or silicon germanium oxide. The second oxide layer may comprise a metal oxide comprising at least one of: magnesium oxide (MgO), aluminum oxide (Al₂O₃), zirconium oxide (ZrO2), hafnium oxide (HfO2), hafnium silicon oxide (HfSiO), tantalum oxide (Ta2O5), tantalum silicon oxide (TaSiO), barium strontium titanate (BST), and strontium bismuth tantalate (SBT). The second oxide layer may comprise an oxide comprising at least one of: scandium (Sc), yttrium (Y), lanthanum (La), cerium Ce, praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb) and lutetium (Lu), as well as silicon nitride (SiN).

In some examples, the thickness of the second layer may be about between 0.5 and 30 angstroms thick. Contacting the etched surface of the substrate with the oxidizing agent may further comprise supporting the substrate in a first reaction chamber and flowing the oxidizing agent into the first reaction chamber. Depositing the second layer may further comprise depositing a second oxide layer in the first reaction chamber.

In some examples, depositing the second layer may further comprise depositing a second oxide layer in a second reaction chamber.

In various examples, etching the native oxide from the surface of the substrate may further comprise etching the native oxide in the first reaction chamber.

In other examples, etching the native oxide from the surface of the substrate may further comprise etching the native oxide in a second reaction chamber.

In some examples, etching the native oxide from the surface of the substrate may further comprise etching the native oxide in the first reaction chamber and wherein depositing the second layer may further comprise depositing a second oxide layer in the first reaction chamber.

For the purpose of summarizing the disclosure and the advantages achieved over the prior art, certain objects and advantages of the disclosure have been described herein above. Of course, it is to be understood that not necessarily all such objects or advantages can be achieved in accordance with any particular embodiment or example of the disclosure. Thus, for example, those skilled in the art will recognize that the examples disclosed herein can be carried out in a manner that achieves or optimizes one advantage or group of advantages as taught or suggested herein without necessarily achieving other objects or advantages as can be taught or suggested herein.

All of these examples are intended to be within the scope of the disclosure. These and other embodiments will become readily apparent to those skilled in the art from the following detailed description of certain examples having reference to the attached figures, the disclosure not being limited to any particular example(s) discussed.

### BRIEF DESCRIPTION OF THE DRAWING FIGURES

While the specification concludes with claims particularly pointing out and distinctly claiming what are regarded as embodiments or examples of the disclosure, the advantages of examples of the disclosure may be more readily ascertained from the description of certain examples of the disclosure when read in conjunction with the accompanying drawings. Elements with the like element numbering throughout the figures are intended to be the same.

FIG. 1A illustrates a schematic diagram of a reactor system, in accordance with an example of the present technology.

FIG. 1B illustrates a schematic diagram of a reactor system, in accordance with an example of the present technology.

FIG. 2 illustrates a schematic diagram of a reactor system having multiple reaction chambers, in accordance with an example of the present technology.

FIG. 3 illustrates a device structure, in accordance with an example of the present technology.

FIG. 4 illustrates a processing method, in accordance with an example of the present technology.

FIG. 5 illustrates a processing method, in accordance with an example of the present technology.

### DETAILED DESCRIPTION

The detailed description of various examples herein makes reference to the accompanying drawings, which show the exemplary examples by way of illustration. While these exemplary examples are described in sufficient detail to enable those skilled in the art to practice the disclosure, it should be understood that other examples may be realized and that logical, chemical, and/or mechanical changes may be made without departing from the spirit and scope of the disclosure. Thus, the detailed description herein is presented for purposes of illustration only and not of limitation. For example, the steps recited in any of the method or process descriptions can be executed in any combination and/or order and are not limited to the combination and/or order presented. Further, one or more steps from one of the disclosed methods or processes can be combined with one or more steps from another of the disclosed methods or processes in any suitable combination and/or order. Moreover, any of the functions or steps can be outsourced to or performed by one or more third parties. Furthermore, any reference to singular includes plural examples, and any reference to more than one component can include a singular example.

Although certain embodiments and examples are disclosed below, it will be understood by those in the art that the disclosure extends beyond the specifically disclosed examples and/or uses of the disclosure and obvious modifications and equivalents thereof. Thus, it is intended that the scope of the disclosure should not be limited by the particular examples described herein.

The illustrations presented herein are not meant to be actual views of any particular material, apparatus, structure, or device, but are merely representations that are used to describe examples of the disclosure.

As used herein, the term “substrate” can refer to any underlying material or materials that may be used, or upon which, a device, a circuit, or a film/layer may be formed.

As used herein, the term “atomic layer deposition” (ALD) can refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) can subsequently be introduced into the process chamber for use in converting the chemisorbed precursor to the desired material on the deposition surface. Typically, this reactant is capable of further reaction with the precursor. Further, purging steps can also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) can refer to any process wherein a substrate is exposed to one or more volatile precursors, which react and/or decompose on a substrate surface to produce a desired deposition.

As used herein, the terms “layer,” “film,” and/or “thin film” can refer to any continuous or non-continuous structures and material deposited by the methods disclosed herein. For example, “layer,” “film,” and/or “thin film” could include 2D materials, nanorods, nanotubes, or nanoparticles or even partial or full molecular layers or partial or full atomic layers or clusters of atoms and/or molecules. “Layer,” “film,” and/or “thin film” can comprise material or a layer with pinholes, but still be at least partially continuous.

Further, in this disclosure, any two numbers of a variable can constitute a workable range of the variable, and any ranges indicated can include or exclude the endpoints. Additionally, any values of variables indicated (regardless of whether they are indicated with “about” or not) can refer to precise values or approximate values and include equivalents, and can refer to average, median, representative, majority, or the like. Further, in this disclosure, the terms “including,” “constituted by” and “having” can refer independently to “typically or broadly comprising,” “comprising,” “consisting essentially of,” or “consisting of” in some examples. In this disclosure, any defined meanings do not necessarily exclude ordinary and customary meanings in some examples.

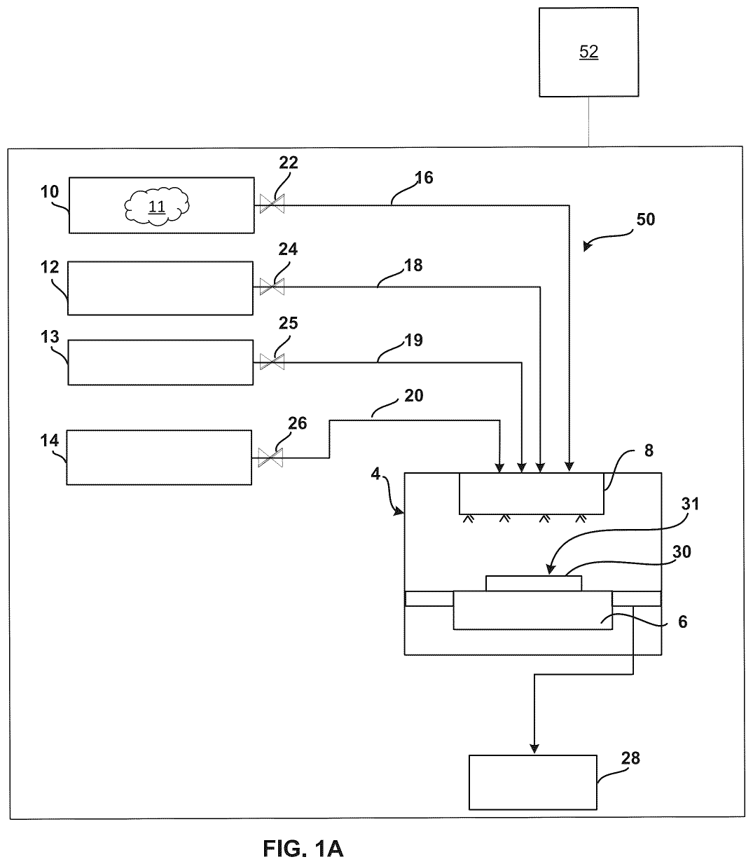

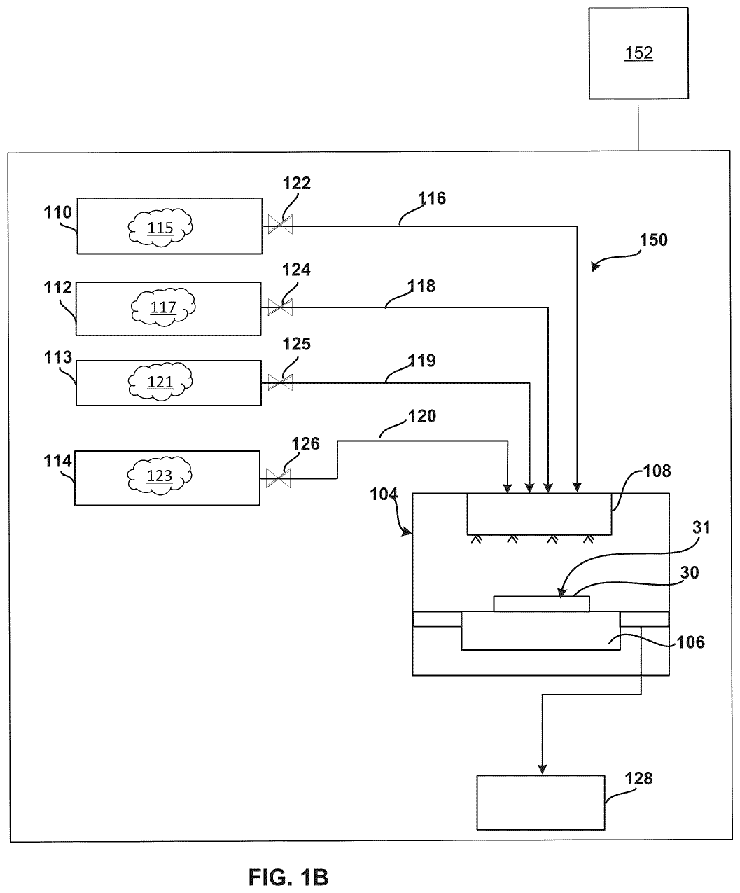

FIG. 1A illustrates a schematic diagram of a reactor system 50, in accordance with examples of the present technology. Reactor systems used for ALD, CVD, and/or the like, may be used for a variety of applications, including depositing and/or etching materials on a substrate surface. As used herein, the term “surface” may refer to any portion of an exposed semiconductor surface. For example, the surface may be the entire exterior of a semiconductor substrate and/or layer or a portion thereof or a top surface of a semiconductor substrate and/or layer thereon or a portion of either.

In various examples, a reactor system 50 can comprise a reaction chamber 4, a susceptor 6 to hold a substrate 30 during processing, a fluid distribution system 8 (e.g., a showerhead) to distribute one or more reactants to a surface of substrate 30, one or more reactant sources 10, 12, and/or 13, and/or a carrier and/or purge gas source 14, fluidly coupled to reaction chamber 4 via respective lines 16, 18, 19 and 20, and respective valves or controllers 22, 24, 25 and 26. Reactant gases or other materials from reactant sources 10, 12 and/or 13 can be applied to substrate 30 in reaction chamber 4. A purge gas from purge gas source 14 can be flowed to and through reaction chamber 4 to remove any excess reactant or other undesired materials from reaction chamber 4. System 50 can also comprise a vacuum source 28 fluidly coupled to the reaction chamber 4, which can be configured to evacuate reactants, a purge gas, or other materials out of reaction chamber 4.

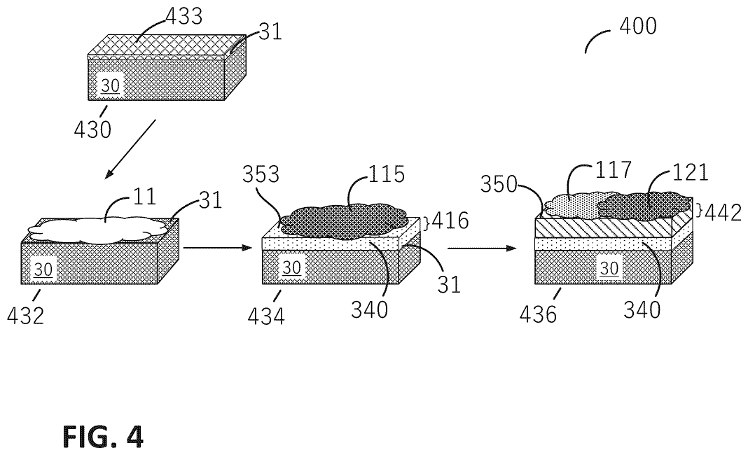

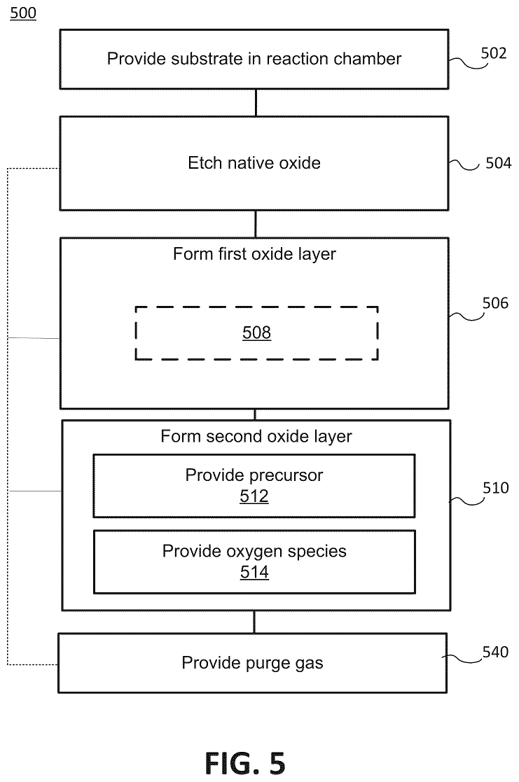

Controller 52 can be configured to perform various functions and/or steps as described herein. Controller 52 can include one or more microprocessors, memory elements, and/or switching elements to perform the various functions. Although illustrated as a single unit, controller 52 can alternatively comprise multiple devices. By way of example, controller 52 can be used to control gas flow (e.g., by monitoring flow rates and controlling valves 22, 24, 25 and/or 26), motors, heaters, cooling devices and/or vacuum source 28 to execute various processes (e.g., method 400 in FIG. 4 and/or method 500 in FIG. 5). Further, when a system includes two or more reaction chambers, as described in more detail below, the two or more reaction chambers can be coupled to the same/shared controller.

In an example, substrate 30 may comprise Si or SiGe and may have a layer of native oxide on a top surface. In some examples, surface 31 may be prepared for subsequent surface treatment by removing the native oxide from top surface 31. Such cleaning may be performed prior to loading the substrate 30 into reaction chamber 4. For example, an ex-situ process for removal of native oxide may be performed using a wet chemical clean, such as by diluted hydrogen fluoride solution (HF with deionized water).

In another example, the cleaning process may be performed after loading substrate 30 into reaction chamber 4 in an in-situ process. In such an example, reactor system 50 may be configured to perform the cleaning process to etch and/or otherwise remove the native oxide. Accordingly, reactant source 10 may contain an etchant such as chemical species 11, which includes solid, liquid and/or gas phase chemicals to clean a surface 31 of substrate 30 prior to deposition. For example, chemical species 11 may include chemicals capable of removing native oxides from surface 31 by contacting surface 31. As a non-limiting example, such chemical species 11 may include but are not limited to hydrogen chloride (HCl), hydrogen fluoride (HF), ammonium hydroxide (NH4OH), hydrogen (H2), and hydrogen plasma.

In an example, subsequent to removal of native oxide, surface 31 may be hydrogen terminated. Such hydrogen termination may lead to nucleation delay and island formation during deposition of subsequent films on surface 31. A surface treatment may be applied to replace terminal hydrogen attached at surface 31 with a hydroxyl group (i.e., couple hydroxyl (OH) groups to molecules at surface 31). Reactor system 50 may be configured to perform such a surface treatment. Alternatively, surface treatment to hydroxylate surface 31 of substrate 30 may be performed in a different reaction chamber such as reaction chamber 104 shown in FIG. 1B.

Referring now to FIG. 1B, in various examples, a reactor system 150 can comprise a reaction chamber 104, a susceptor 106 to hold a substrate 30 during processing, a fluid distribution system 108 (e.g., a showerhead) to distribute one or more reactants to a surface of substrate 30, one or more reactant sources 110, 112, and/or 113, and/or a carrier and/or purge gas source 114, fluidly coupled to reaction chamber 104 via respective lines 116, 118, 119 and 120, and respective valves or controllers 122, 124, 125 and 126. Reactant gases (e.g., oxidizing agent 115, precursor 117 and/or oxygen species 121) or other materials from sources 110, 112, and/or 113 can be applied to substrate 30 in reaction chamber 104. Purge gas 123 from gas source 114 can be flowed to and through reaction chamber 104 to remove any excess reactant or other undesired materials from reaction chamber 104. System 150 can also comprise a vacuum source 128 fluidly coupled to the reaction chamber 104, which can be configured to evacuate reactants, a purge gas, or other materials out of reaction chamber 104.

Controller 152 can be configured to perform various functions and/or steps as described herein. Controller 152 can include one or more microprocessors, memory elements, and/or switching elements to perform the various functions. Although illustrated as a single unit, controller 52 can alternatively comprise multiple devices. By way of example, controller 152 can be used to control gas flow (e.g., by monitoring flow rates and controlling valves 122, 124, 125 and/or 126), motors, heaters, cooling devices and/or vacuum source 128 to execute various processes (e.g., method 400 in FIG. 4 and/or method 500 in FIG. 5). Further, when a system includes two or more reaction chambers, as described in more detail below, the two or more reaction chambers can be coupled to the same/shared controller.

In an example, a surface treatment to oxidize surface 31 may comprise pulsing oxidizing agent 115 (e.g., H2O2 vapor) from reactant source 110 to reaction chamber 104 via showerhead 108. Oxidizing agent 115 may contact surface 31 of substrate 30 to oxidize substrate 30 surface and replace hydrogen with OH groups at hydrogen terminated surface molecules. This may reduce nucleation delay in subsequent oxide formation. Moreover, consumption of substrate 30 Si and/or SiGe may be minimized because H2O2 is a relatively weak oxidizing agent. Thus, surface oxide thickness can be minimized. With this approach surface oxide thickness may be limited to less than or equal to about 4 angstroms.

Subsequent to forming the first oxide layer on substrate 30 with treatment using oxidizing agent 115, a second oxide layer deposited on surface 31 may have reduced nucleation delay and island formation leading to smoother and faster closure and a more uniform surface film.

In an example, first and second oxide layers may be deposited in the same chamber or may be deposited in different chambers. The second oxide layer may be formed by any of a variety of methods known to those of skill in the art. For example, forming the second oxide layer may comprise providing a precursor 117 and/or oxygen source 121 to the reaction chamber 104 through showerhead 108 to substrate 30 and purging the chamber 104 with purge gas 123 at various intervals.

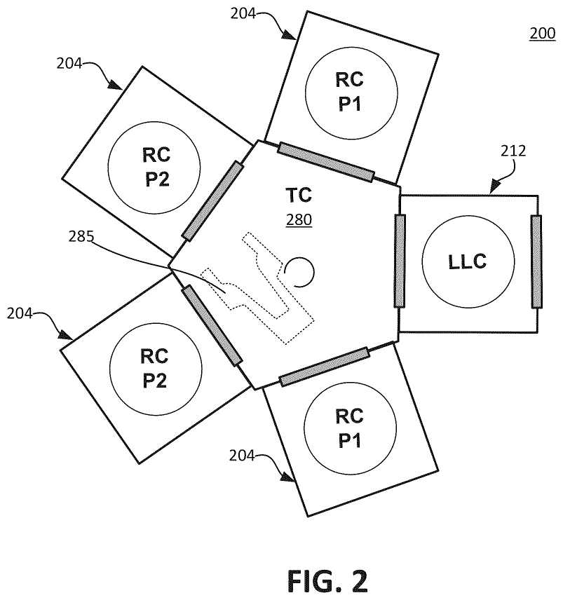

In some examples, a reactor system (e.g., reactor system 50 or reactor system 150) can comprise multiple reaction chambers. For example, in reactor system 200, shown in FIG. 2, a number of reaction chambers 204 (each of which can be an example of reaction chamber 4 or reaction chamber 104 in respective FIGS. 1A and 1B) can be disposed around and/or coupled to a transfer chamber 280 comprising a transfer tool 285 for transferring substrates between reaction chambers 204. Substrates can be transferred from a load lock chamber 212 and between reaction chambers 204 (e.g., through transfer chamber 280). For example, a substrate 30 can be disposed in different chambers for different steps of a semiconductor manufacturing process (e.g., etching, oxidizing, passivation and/or deposition steps may each be performed in the same or different chambers).

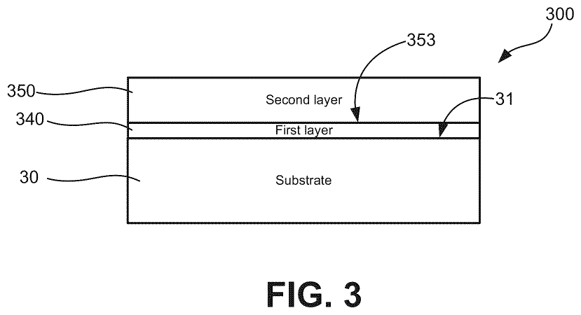

FIG. 3 illustrates a structure 300 in accordance with examples of the disclosure. Device structure 300 can be any of a variety of semiconductor structures. Structure 300 includes a substrate 30 (e.g., Si or SiGe), a first oxide layer 340 comprising an oxide (e.g., silicon oxide (SiOx) or silicon germanium oxide (SiGeOx)) and a second oxide layer 350 (e.g., metal oxide or lanthanide oxide). First oxide layer 340 may over lie a top surface 31 of substrate 30. In an example, second layer 350 may over lie first oxide layer 340. Structure 300 may be formed according to examples described herein.

FIG. 4 illustrates an example process 400 for forming a structure 300 in accordance with examples of the disclosure. With combined reference to FIGS. 1A, 1B, 3 and 4, method 400 can comprise providing a substrate 30 in a reaction chamber (e.g., reaction chamber 4 in FIG. 1A). Substrate 30 can be disposed on a susceptor (e.g., susceptor 6 in FIG. 1A) for processing.

In an example, process 400 may begin at operation 430 with provision of a substrate 30 within a chamber (e.g., chamber 4 or chamber 104).

Process 400 may move to operation 432 wherein an etchant such as chemical species 11 (e.g., HF, HCl, NH4OH, and/or H2) may be flowed into the chamber to contact top surface 31 of substrate 30. Chemical species 11 may be a liquid or gas and may comprise any of a variety of etchants known to those of skill in the art. Chemical species 11 may be configured to remove a native oxide 433 formed on surface 31 by etching. Etching native oxide 433 from surface 31 may leave surface 31 hydrogen terminated. Such hydrogen termination tends to be less reactive or inert and may lead to nucleation delay in formation of subsequent oxide layers.

Process 400 may proceed to operation 434 where oxidizing agent 115 may be flowed into the chamber to contact surface 31. Operation 434 may take place within the same or a different chamber as operation 432 (e.g., chamber 4 or chamber 104). First oxide layer 340 may be formed by oxidizing the surface 31 of substrate 30. In an example, oxidizing agent 115 may comprise an oxidizer that is weaker than O3 (e.g., H2O2). In contrast to conventional methods, process 400 disclosed herein includes depositing first oxide layer 340 using a relatively weak oxidizing agent (e.g., H2O2) to minimize consumption of Si and/or SiGe such that first oxide layer 340 thickness is minimized. Use of a weak oxidizing agent may promote control over diffusion of the oxidizer into substrate 30 enabling development of a thin first oxide layer 340. Additionally, by controlling the temperature of the oxidizing agent 115, the thickness 416 of first oxide layer 340 may be constrained. Thus, the temperature of the oxidizing agent and/or substrate 30 may be modified before or while the oxidizing agent 115 contacts the substrate 30 based on a desired thickness of first oxide layer 340. In an example, the temperature of the oxidizing agent 115 may be controlled by controlling substrate 30 temperature and/or by controlling the temperature of the oxidizing agent 115. Substrate 30 temperature may be controlled within chamber 4 or 104 by controlling the temperature of the susceptor 6 or 106. In an example, contacting surface 31 of substrate 30 with oxidizing agent 115 may include changing the temperature of substrate 30 while in contact with the oxidizing agent 115 to control the thickness of first oxide layer 340 in real time, for example, by controlling the temperature of the susceptor (e.g., susceptor 6 or 106) or adjusting a temperature of oxidizing agent 115 contacting the substrate.

In an example, use of a weak oxidizer such as H2O2 vapor as the oxidizing agent 115 may create a first oxide layer 340 with abundant OH groups at the surface (e.g., surface 353) by hydroxylating a portion of molecules on etched surface 31. Replacing the hydrogen terminated surface left by etching native oxide 433 from surface 31 with OH groups may reduce nucleation delay in formation of subsequent oxide layers.

In an example, first oxide layer 340 may be formed to a thickness 416 in the range of about 0.1 to 20 angstroms or about 18 angstroms, or between about 0.5 to 16 angstroms or about 14 angstroms, or between about 1 to 12 angstroms, or about 10 angstroms, or between about 1 to 8 angstroms or about 6 angstroms, or between about 1 to 6 angstroms or about 4 angstroms (“about” in this context means plus or minus 2 angstroms) or any other suitable thickness. In some examples, the thickness 416 of first oxide layer 340 is less than or equal to 5 angstroms.

In some embodiments, contacting substrate 30 with an oxidizing agent 115 may comprise pulsing the oxidizing agent 115 into the reaction chamber and subsequently contacting the substrate 30 for a time period of between about 0.01 seconds and about 60 seconds, or between about 0.01 seconds and about 50 seconds, or between about 0.01 seconds and about 40 seconds, or between about 0.01 seconds and about 30 seconds, or between about 0.01 seconds and about 20 seconds, or between about 0.01 seconds and about 10 seconds, or between about 0.01 seconds and about 5.0 seconds (“about” in this context means plus or minus 5 seconds) or any other suitable duration. Pulsing may be alternating or sequential. In some embodiments, oxidizing agent 115 may be pulsed over about 1 cycle to about 100 cycles, or about 1 cycle to about 80 cycles, or about 1 cycle to about 60 cycles, or about 1 cycle to about 40 cycles, or about 1 cycle to about 30 cycles, or about 1 cycle to about 15 cycles (“about” in this context means plus or minus 15 cycles) or any suitable number of cycles. In some embodiments, operation 434 may be pulsed for a duration of about 30 seconds for about 30 cycles.

The temperature during the steps to form the first oxide layer 340 can be between about 100° C. and 500° C., or about 450° C., or between about 100° C. and 400° C., or about 350° C. or between about 100° C. and 300° C., or about 250° C., or between about 100° C. and 200° C., or about 150° C. (“about” in this context means plus or minus 50° C.) or any sufficient temperature.

In an example, process 400 may proceed to operation 436 where a second oxide layer 350 may be formed on first oxide layer 340. In various examples, forming the second oxide layer 350 may comprise providing a precursor 117 and/or an oxygen species 121 to the reaction chamber (e.g., reaction chamber 4 or reaction chamber 104). Precursor 117 can be provided through a showerhead (e.g., showerhead 8 or showerhead 108) to substrate 30, or through a crossflow fluid distribution system. In an example, precursor 117 may be a metal-containing precursor for forming of metallic oxides including but not limited to magnesium oxide (MgO), aluminum oxide (Al2O3), zirconium oxide (ZrO2), hafnium oxide (HfO2), hafnium silicon oxide (HfSiO), tantalum oxide (Ta2O5), tantalum silicon oxide (TaSiO), barium strontium titanate (BST), and strontium bismuth tantalate (SBT). In other examples, precursor 117 may comprise lanthanide oxides, oxides of physically stable “rare earth” elements such as scandium (Sc), yttrium (Y), lanthanum (La), cerium Ce, praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb) and lutetium (Lu), as well as silicon nitride (SiN). Precursor 117 can be pulsed into the reaction chamber for any suitable duration (e.g., for pulse times of between 0.05 to 60 seconds). The pressure within the reaction chamber during provision of the first precursor can be any suitable pressure, such as between 1 and 10 Torr.

In various examples, forming second oxide layer 350 may further comprise providing oxygen species 121 to the reaction chamber. Oxygen species 121 can be provided through a showerhead (e.g., showerhead 8 or showerhead 108) to substrate 30, or through a crossflow fluid distribution system. The oxygen species 121 can be pulsed into the reaction chamber for any suitable duration (e.g., for pulse times of between 0.05 to 60 seconds). In various examples, the oxygen species can be continuously provided to the reaction chamber. The pressure within the reaction chamber during provision of the oxygen species can be any suitable pressure, such as between 1 and 10 Torr. In various examples, the first oxygen species can comprise any suitable compound comprising oxygen and/or oxidizing compound, such as water (H₂O), ozone (O₃), hydrogen peroxide (H₂O₂), deuterium oxide (D₂O), nitrous oxide (N₂O), nitrogen dioxide (NO₂), and/or an alcohol (e.g., tertbutyl alcohol), or the like or combinations thereof.

The temperature during the steps to form the second oxide layer 350 can be between about 100° C. and 500° C., or about 450° C., or between about 100° C. and 400° C., or about 350° C. or between about 100° C. and 300° C., or about 250° C., or between about 100° C. and 200° C., or about 150° C. (“about” in this context means plus or minus 50° C.) or any sufficient temperature.

The steps of providing precursor 117 and providing oxygen species 121 can be performed in any suitable order. In various examples, the steps of providing precursor 117 and/or oxygen species 121 can be separated by a purge gas 123 to remove excess precursor, byproducts, or other unwanted materials. In various examples, a purge gas can be provided after each step (e.g., after providing the precursor 117 and providing the oxygen species 121, regardless of the order) and/or after deposition of the first oxide layer 340 or after a deposition of the second oxide layer 350 (i.e., a post-deposition purge step).

Second oxide layer 350 may be deposited to any thickness, such as, between about 0.5 and 30 angstroms thick, or about 27 angstroms thick, or between about 1 and 24 angstroms thick, or about 21 angstroms thick, or between about 1 and 18 angstroms thick, or about 15 angstroms thick, or between about 1 and 12 angstroms thick, or about 9 angstroms thick, or between about 1 and 6 angstroms thick, or about 3 angstroms thick (“about” in this context means plus or minus 3 angstroms) or any other suitable thickness.

With reference to FIGS. 1A, 1B, 3 and 4, FIG. 5 depicts a method 500 of depositing layers on a substrate to form device structure 300.

In examples, method 500 may begin at operation 502 where a substrate is supported in a reaction chamber (e.g., reaction chamber 4 or reaction chamber 104). The substrate may comprise any suitable material, such as, but not limited to silicon (Si), germanium (Ge) or silicon germanium (SiGe).

In an example, method 500 may move to operation 504 where a native oxide (e.g., native oxide 433) on surface 31 of substrate 30 may be etched responsive to exposure to an etchant. The etchant may be applied as a liquid or a gas. The etchant may comprise any suitable etchant such as, but not limited to, hydrogen chloride (HCl), hydrogen fluoride (HF), ammonium hydroxide (NH4OH), or hydrogen (H2) or a combination thereof. Method 500 may move to operation 540 where a purge gas may be provided to the reaction chamber to remove excess precursor, byproducts, or other unwanted materials. Purge gas may be provided between pulses of etchant and/or upon completion of etchant pulsing.

In an example, method 500 may continue to operation 506, where a first oxide layer 340 may be formed by contacting surface 31 with an oxidizing agent 115. Oxidizing agent 115 may diffuse into substrate 30 from surface 31 and oxidize a top layer of substrate 30 to form an oxide layer (e.g., silicon oxide (SiOx) or silicon germanium oxide (SiGeOx)). Oxidizing the top portion of substrate 30 forms first oxide layer 340. The oxidizing agent 115 may be a weaker oxidizer than ozone (O3). For example, oxidizing agent 115 may be hydrogen peroxide (H2O2).

In an example, oxidizing agent 115 may contact substrate 30 in a vapor phase oxidizing the substrate 30 to a depth of less than about 10 angstroms with respect to a top surface 31, or less than about 5 angstroms with respect to a top surface 31 (“about” in this context means plus or minus 5 angstroms) or to any sufficient depth.

In an example, oxidizing top surface 31 of the substrate 30 further comprises hydroxylating a portion of the molecules at the etched surface 31 of substrate 30. Such hydroxylated surface 31 portion may be less likely to cause nucleation delay in formation of subsequent oxide layers by reduction of island formation and/or faster film closing. This may improve roughness of subsequent film deposition.

At operation 508, in an example, contacting the surface 31 of the substrate 30 with the oxidizing agent 115 may further comprise modifying the temperature of the substrate 30 and/or oxidizing agent 115 before, during, and/or after oxidizing agent 115 is in contact with substrate 30. Adjusting the temperature of the substrate 30 may impact the thickness of first oxide layer 340. Thus, adjustment to temperature may be made based on a desired thickness of the first oxide layer 340. Temperature modification may be made by changing the temperature of the susceptor (e.g., susceptor 6 or susceptor 106) or otherwise changing the temperature of the oxidizing agent 115 by other means known to those of skill in the art.

Method 500 may move to operation 540 where a purge gas may be provided to the reaction chamber to remove excess precursor, byproducts, or other unwanted materials. Purge gas may be provided before, between and/or after pulses of oxidizing agent 115 and/or upon completion of oxidizing agent pulsing or completion of formation of first oxide layer 340.

In an example, method 500 may continue to operation 510, where a second oxide layer 350 may be formed on first oxide layer 340. Forming the second oxide layer 350 may comprise providing a precursor 117 at operation 512 and/or an oxygen species 121 at operation 514 to the reaction chamber (e.g., reaction chamber 4 or reaction chamber 104).

Operations 512 and 514 may be performed in any suitable order. Method 500 may move to operation 540 where a purge gas may be provided to the reaction chamber to remove excess precursor, byproducts, or other unwanted materials. Purge gas may be provided prior to, between and/or after pulses of precursor 117 and/or oxygen species 121 and/or upon completion of formation of second oxide layer 350.

In various examples, a purge gas 123 can be provided (operation 540) after each step (e.g., after providing the precursor 117 and providing the oxygen species 121, regardless of the order) and/or after deposition of the first oxide layer 340 or after a deposition of the second oxide layer 350 (i.e., a post-deposition purge step).

Although exemplary examples of the present disclosure are set forth herein, it should be appreciated that the disclosure is not so limited. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. A method for depositing one or more layers on a substrate, comprising:
a) providing a substrate;
b) etching a native oxide from a surface of the substrate responsive to exposure to an etchant;
c) contacting an etched surface of the substrate with an oxidizing agent;
d) oxidizing a first layer of the substrate responsive to contact with the oxidizing agent; and
e) depositing a second layer on the first layer.

2. The method of claim 1, wherein the etchant is a chemical in gas phase.

3. The method of claim 1, wherein the etchant is a chemical in liquid phase.

4. The method of claim 1, wherein the etchant may comprise hydrogen chloride (HCl), hydrogen fluoride (HF), ammonium hydroxide (NH4OH), or hydrogen (H2) or a combination thereof.

5. The method of claim 1, wherein the substrate comprises silicon (Si), germanium (Ge) or silicon germanium (SiGe).

6. The method of claim 1, wherein the oxidizing agent is a weaker oxidizer than ozone (O3).

7. The method of claim 1, wherein the oxidizing agent is H2O2.

8. The method of claim 7, wherein the oxidizing agent contacts the substrate in a vapor phase.

9. The method of claim 8, wherein oxidizing the first layer of the substrate further comprises oxidizing the substrate to a depth of less than 10 angstroms with respect to a top surface of the substrate.

10. The method of claim 8, wherein oxidizing the first layer of the substrate further comprises oxidizing the substrate to a depth of less than five angstroms with respect to a top surface of the substrate.

11. The method of claim 1, wherein oxidizing the first layer of the substrate further comprises hydroxylating a portion of molecules at the etched surface of the substrate.

12. The method of claim 1, wherein the contacting the surface of the substrate with the oxidizing agent further comprises modifying a temperature of the substrate while in contact with the oxidizing agent based on a desired thickness of the first oxide layer.

13. The method of claim 12, wherein the modifying the temperature of the substrate further comprises heating a susceptor coupled to the substrate or adjusting a temperature of the oxidizing agent contacting the substrate.

14. The method of claim 1, wherein the first layer is a first oxide layer and wherein the second layer is a second oxide layer.

15. The method of claim 14, wherein the first oxide layer is silicon oxide or silicon germanium oxide.

16. The method of claim 14, wherein the second oxide layer is a metal oxide comprising at least one of: magnesium oxide (MgO), aluminum oxide (Al2O3), zirconium oxide (ZrO2), hafnium oxide (HfO2), hafnium silicon oxide (HfSiO), tantalum oxide (Ta2O5), tantalum silicon oxide (TaSiO), barium strontium titanate (BST), and strontium bismuth tantalate (SBT).

17. The method of claim 14, wherein the second oxide layer is an oxide comprising at least one of: scandium (Sc), yttrium (Y), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb) and lutetium (Lu).

18. The method of claim 1, wherein the thickness of the second layer is about between 0.5 and 30 angstroms thick.

19. The method of claim 1, wherein the contacting the etched surface of the substrate with the oxidizing agent further comprises:
supporting the substrate in a first reaction chamber; and
flowing the oxidizing agent into the first reaction chamber.

20. The method of claim 1, wherein depositing the second layer further comprises depositing a second oxide layer in the first reaction chamber.

21. The method of claim 19, wherein depositing the second layer further comprises depositing a second oxide layer in a second reaction chamber.

22. The method of claim 19, wherein etching the native oxide from the surface of the substrate further comprises etching the native oxide in the first reaction chamber.

23. The method of claim 19, wherein etching the native oxide from the surface of the substrate further comprises etching the native oxide in a second reaction chamber.

24. The method of claim 19, wherein etching the native oxide from the surface of the substrate further comprises etching the native oxide in the first reaction chamber and wherein depositing the second layer further comprises depositing a second oxide layer in the first reaction chamber.
